(19) United States
(12) Patent Application Publication
(10) Pub. No.: US 2011/0294067 A1
(43) Pub. Date: Dec. 1, 2011

(54) PHOTOSENSITIVE RESIN COMPOSITION

(75) Inventors: Chih-Han Chao, Taoyuan (TW); Chun-Chin Chou, Taoyuan (TW); Yu-Ling Lin, Taoyuan (TW); Chih-Yi Chang, Taoyuan (TW)

(73) Assignee: EVERLIGHT USA, INC., Pineville, NC (US)

(21) Appl. No.: 13/070,551

(22) Filed: Mar. 24, 2011

(30) Foreign Application Priority Data
Jun. 1, 2010 (TW) 99117533

(51) Int. Cl. G03F 7/004

(52) U.S. Cl. 430/280.1

(57) ABSTRACT

A photosensitive resin composition is disclosed. The photosensitive resin composition includes an alkali soluble resin with an epoxy structure, a photopolymerizable compound having an ethylenically unsaturated bond, a photoinitiator, and a thermal curing agent. The photosensitive resin composition provides great surface hardness, adhesion and transmittance to meet industrial requirements.

### 1. FIELD OF INVENTION

The present invention relates to a resin composition, and more particularly, to a negative photosensitive resin composition.

### 2. BACKGROUND OF THE INVENTION

Photosensitive materials absorb light energy and thus have priority change, linkage breakage or crosslink due to intra-reaction or inter-reaction, such that there is a difference of solubility between exposure regions and non-exposure regions in developing solution. Negative photosensitive materials have cross-link reactions upon exposure and thus difficult to be dissolved in developing solution. In contrast, positive photosensitive materials are easily dissolved in developing solution upon exposure, such that exposure regions are removed due to dissolution in developing solution. Photolithography forms fine patterns on electronic components via photosensitive materials, exposure, development, and etc. In photolithography, a substrate is covered by the photosensitive material, the photosensitive material is selectively exposed via a mask, development is performed due to the difference of dissolution rates between exposure regions and non-exposure regions, and patterns (such as wiring patterns) on the mask are transferred to the photosensitive material. Currently, photosensitive materials are widely used in printed circuit boards, integrated circuits, LCD display panels and MEMS for forming a photoresist agent and a protection layer or insulation layer in an electronic component. Japanese Patent Application No. JP2007-156139 discloses a photosensitive resin composition for forming a photo spacer with great elasticity in LCD displays.

Due to the trend of minimization and integration, photosensitive materials are strictly required. In order to meet high resolution, reliability and yield, photosensitive materials need to have high photosensitivity, high transmittance, high surface hardness, high thermal resistance, high flatness, high corrosion resistance, low thermal expansion and high adhesion to a substrate (such as ITO in an LCD display panel or a touch panel). U.S. Pat. No. 7,374,861 discloses a photosensitive composition including a polyimide, an unsaturated vinyl monomer that contains a tertiary amino group, and a photoinitiator for reducing development period via the monomer. Japanese Patent No. 3994429 discloses a resin composition for a thin film in an LCD display panel, an integrated circuit device and a solid state image pickup device, so as to provide great surface smoothness, heat resistance, transparency and chemical resistance. U.S. Pat. No. 6,432,616 discloses introducing a side chain having an unsaturated bond and/or a hetero atom into a polymer to increase photosensitivity of a photosensitive material and adhesion to a copper substrate. Taiwanese Patent No. 180311 discloses a photoresist for short wavelength imaging, so as to provide great resolution and adhesion to a copper substrate. However, there is still a need to develop a material with high surface hardness and high transmittance.

### SUMMARY OF THE INVENTION

The present invention provides a photosensitive resin composition, including 10 to 50 wt % of an alkali soluble resin (A) based on a total weight of the photosensitive resin composition, wherein the alkali soluble resin (A) includes a monomer (a1) selected from the group consisting of an acrylic monomer, an acrylic anhydride and a mixture thereof; and an acrylic monomer (a2) with an epoxy structure; 1 to 10 wt % of a photopolymerizable compound (B) having an ethylenically unsaturated bond based on the total weight of the photosensitive resin composition; 1 to 10 wt % of a photoinitiator (C) based on the total weight of the photosensitive resin composition; and 1 to 10 wt % of a thermal curing agent (D) based on the total weight of the photosensitive resin composition.

According to an embodiment of the present invention, the acrylic monomer is acrylic acid or methyl acrylic acid, and an unsaturated carboxylic anhydride is acrylic anhydride or methyl acrylic anhydride.

According to an embodiment of the present invention, the acrylic monomer with an epoxy structure has a structure of formula (I):

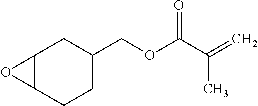

According to an embodiment of the present invention, the alkali soluble resin has an average molecular weight in a range of from 5000 to 15000.

According to an embodiment of the present invention, the alkali soluble resin further includes an active monomer (a3). The active monomer (a3) is an ethylenically unsaturated monomer or a modified acrylic monomer.

According to an embodiment of the present invention, the thermal curing agent has a structure of formula (II):

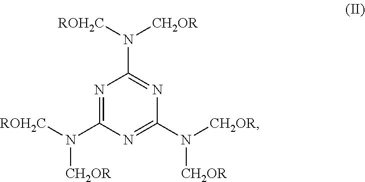

wherein R is H or CH₃.

In one embodiment of the present invention, the thermal curing agent has a structure of formula (III):

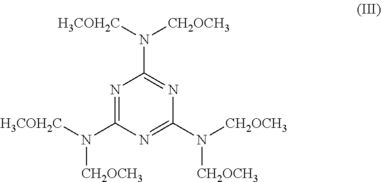

In an embodiment of the present invention, the photosensitive resin composition may optionally include a solvent. According to an embodiment of the present invention, the photosensitive resin composition may optionally include an additive.

The photosensitive resin composition has an alkali soluble resin with an epoxy resin and a thermal curing agent, such that surface hardness may be increased, and great adhesion and transmittance are provided due to the thermal agent working in a cross-link reaction.

### DETAILED DESCRIPTION OF THE PREFERRED EMBODIMENTS

The following specific examples are used for illustrating the present invention. A person skilled in the art can easily conceive the other advantages and effects of the present invention.

The term “average molecular weight” herein refers to a measured value of a sample in a tetrahydrofuran relative to a polystyrene standard by gel penetration chromatography (GPC).

The term “acrylic” herein refers to acrylic acid and methyl acrylic acid. The term “(meth)acrylic acid” includes methyl acrylic acid and acrylic acid. Similarly, (meth)acrylic anhydride includes acrylic anhydride and methyl acrylic anhydride.

The present invention provides a photosensitive resin composition to meet industrial requirements. The photosensitive resin composition includes 10 to 50 wt % of an alkali soluble resin (A) based on a total weight of the photosensitive resin composition, wherein the alkali soluble resin (A) includes a monomer (a1) selected from the group consisting of an acrylic monomer, an acrylic anhydride and a mixture thereof; and a copolymer of an acrylic monomer (a2) with an epoxy structure; 1 to 10 wt % of a photopolymerizable compound (B) having an ethylenically unsaturated bond based on the total weight of the photosensitive resin composition; 1 to 10 wt % of a photoinitiator (C) based on the total weight of the photosensitive resin composition; and 1 to 10 wt % of a thermal curing agent (D) based on the total weight of the photosensitive resin composition.

According to an embodiment of the present invention, the monomer selected from an acrylic monomer, an acrylic anhydride and a mixture thereof is preferably (meth)acrylic acid. According to an embodiment of the present invention, the acrylic anhydride is preferably (meth)acrylic anhydride.

In one embodiment of the present invention, the alkali soluble resin includes 1 to 10 wt %, and preferably 3 to 5 wt %, of the monomer (a1) based on the total weight of the alkali soluble resin.

In the photosensitive resin composition of the present invention, the acrylic monomer with an epoxy structure is not specifically limited, but has an epoxy group and forms copolymers with acrylic monomers and/or acrylic anhydrides.

The acrylic monomer with an epoxy structure may be a (meth)acrylic ester or its derivative. The (meth)acrylic ester or its derivative may be, but not limited to, a (meth)acrylic ester having an oxirane ring and its derivatives such as oxiranyl (meth)acrylates, glycidyl (meth)acrylates, 2-methylglycidyl (meth)acrylates, 2-ethylglycidyl (meth)acrylates, 2-oxiranylethyl (meth)acrylates, 2-glycidyloxyethyl (meth)acrylates, 3-glycidyloxypropyl (meth)acrylates, glycidyloxyphenyl (meth)acrylates and a combination thereof. The (meth)acrylic ester or its derivative may be, but not limited to, a (meth)acrylic ester having 3,4-epoxycyclohexane ring and its derivative such as 3,4-epoxycyclohexyl (meth)acrylates, 3,4-epoxycyclohexylmethyl (meth)acrylates, 2-(3,4-epoxycyclohexyl)ethyl (meth)acrylates, 2-(3,4-epoxycyclohexylmethoxy)ethyl (meth)acrylates, 2-(3,4-epoxycyclohexylmethoxy)propyl (meth)acrylates and a combination thereof. The (meth)acrylic ester or its derivative may be, but not limited to, a (meth)acrylic ester having 5,6-epoxy-2-bicyclo[2.2.1]heptane ring and its derivative such as 5,6-epoxy-2-bicyclo[2.2.1]heptanyl (meth)acrylate. The (meth)acrylic ester or its derivative may be, but not limited to, a (meth)acrylic ester having 3,4-epoxytricyclic[5.2.1.0^{2,6}]decane, a vinyl ether having an epoxy group, an allyl ether and a derivative thereof.

In one embodiment, the acrylic monomer having an epoxy structure is selected from the group consisting of a (meth)acrylic ester having an oxirane ring, a (meth)acrylic ester having a 3,4-epoxycyclohexane ring and a derivative thereof.

In one embodiment, the alkali soluble resin includes 1 to 15 wt %, and preferably 3 to 5 wt % of the acrylic monomer (a2) with an epoxy structure based on the total weight of the alkali soluble resin.

In one embodiment, the acrylic monomer with an epoxy structure has a structure of formula (I):

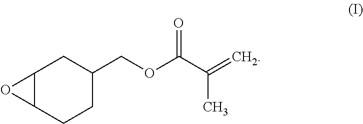

In one embodiment, the alkali soluble resin has an average molecular weight in a range of from 5000 to 15000. In one embodiment, the photosensitive resin composition includes 10 to 50 wt %, preferably 20 to 50 wt %, and more preferably 20 to 40 wt %, of the alkali soluble resin based on the total weight of the photosensitive resin composition.

In one embodiment, a weight ratio of the monomer (a1) selected from the group consisting of the acrylic monomer, the acrylic anhydride and the mixture thereof to the acrylic monomer (a2) with the epoxy structure is in a range of from 1:0.8 to 1:3.

The alkali soluble resin in the photosensitive resin composition of the present invention may be prepared as a copolymer of the monomer (a1) and the acrylic monomer (a2) by a preparation method, which is not limited to the method disclosed in the present invention.

According to an embodiment of the present invention, an active monomer may be optionally added to adjust the characteristic such as surface hardness, flexibility, adhesion capability and adhesiveness, of the alkali soluble resin. In one embodiment, an active monomer may be optionally added for copolymerization with the monomer (a1) and the acrylic monomer (a2) to form the alkali soluble resin. In one embodiment, the alkali soluble resin is a copolymer of the monomer (a1), the acrylic monomer (a2) and an active monomer (a3). In an embodiment, the active monomer is a monomer having ethylene unsaturated bonds.

The monomer having ethylene unsaturated bonds may be, but not limited to, an unsaturated carboxylic ester, an unsaturated aromatic monomer, a monomer having an amide group, vinyl propionate, vinyl acetate and a combination thereof.

The monomer having ethylene unsaturated bonds may be, but not limited to, a (meth)acrylic ester and its derivative such as methyl (meth)acrylates, ethyl (meth)acrylates, propyl (meth)acrylates, isopropyl (meth)acrylates, butyl (meth)acrylates, isobutyl (meth)acrylates, tert-butyl (meth)acrylates, hexyl (meth)acrylates, octanyl (meth)acrylates, lauryl (meth)acrylates, n-octadecyl (meth)acrylates, cyclohexyl (meth)acrylates, ally(meth)acrylates, phenyl (meth)acrylates, benzyl (meth)acrylates, oxetanyl (meth)acrylates, 3-methyl-3-oxetanyl (meth)acrylates, 3-ethyl-3-oxetanyl (meth)acrylates, (3-methyl-3-oxetanyl)methyl (meth)acrylates, (3-ethyl-3-oxetanyl)methyl (meth)acrylates, (3-methyl-3-oxetanyl)ethyl (meth)acrylates, (3-ethyl-3-oxetanyl)ethyl (meth)acrylates, 2-[(3-methyl-3-oxetanyl)methyloxy]ethyl (meth)acrylates, 2-[(3-ethyl-3-oxetanyl)methyloxy]ethyl (meth)acrylates, 3-[(3-methyl-3-oxetanyl)methyloxy]propyl (meth)acrylates, 3-[(3-ethyl-3-oxetanyl)methyloxy]propyl (meth)acrylates, 2-hydroxyethyl (meth)acrylates, tetrahydrofuranylmethyl (meth)acrylates, 2-hydroxypropyl (meth)acrylates, 2-(tricyclo[5.2.1.0^{2,6}]decyloxy)ethyl (meth)acrylates, and a combination thereof; styrene, vinyl toluene (such as o-vinyltoluene, m-vinyltoluene, p-vinyltoluene), α-methylstyrene, chlorostyrene and a combination thereof; an acrylamide derivative such as (meth)acrylamide, N-methylacrylamide, N-ethylmethylacrylamide, N-hydroxymethyl acrylamide, N-hydroxymethylmerhylacrylamide, N-methoxymethyl acrylamide, N-ethoxymethyl acrylamide, N-butoxymethyl acryamide, acrylonitrile and a combination thereof; a maleimide derivative; vinyl propionate, vinyl acetate, vinyl benzoate and a combination thereof; and isobutylene.

In one embodiment, the alkali soluble resin includes 5 to 70 wt %, and preferably 40 to 50 wt %, of the active monomer (a3) based on the total weight of the alkali soluble resin.

The alkali soluble resin in the photosensitive resin composition of the present invention may be prepared as a copolymer of the monomer (a1), the acrylic monomer (a2) and the active monomer (a3) by a preparation method, which is not limited to the method disclosed in the present invention.

The alkali soluble resin may be prepared by polymerization, which is usually performed in the presence of a free radical initiator. The free radical initiator is not specifically limited, and can be a common free radical initiator in the art. One or more free radical initiators may be used. When two or more free radical initiators are mixed and used, the ratio of the mixture is not specifically limited. The amount of the free radical initiator may be 5 to 4 wt % based on the total weight of the alkali soluble resin. The temperature of the polymerization is in a range of from 50 to 90° C., and preferably in a range of from 60 to 70° C.

The polymerization is usually performed in a solvent. Preferably, each component of the alkali soluble resin, the free radical initiator and the obtained resin are dissolved in the solvent. The solvent is not specifically limited, and may be a common solvent in the art. One or more solvents may be used. When two or more solvents are mixed and used, the ratio of the mixture is not specifically limited.

In one embodiment, the obtained alkali soluble resin is mixed with a photopolymerizable compound (B), a photoinitiator (C) and a thermal curing agent to form a photosensitive resin composition.

In the photosensitive resin composition, the photopolymerizable compound is polymerized/cross-linked with the alkali soluble resin upon absorption of light energy. The photopolymerizable compound in the present invention is not specifically limited, but may be polymerized with the alkali soluble resin upon absorption of light energy. According to an embodiment of the present invention, the photopolymerizable compound is a monomer having ethylene unsaturated bonds and/or an oligomer.

Specifically, the photopolymerizable compound may be a compound having multiple carbon-carbon double bonds (a compound having multiple groups, hereafter) for cross-linking reactions. The compound having multiple groups may be, but not limited to a commercial Nikalac MX-302 (Sanwa Chemical Co., Ltd.), Aronix M-400, M-402, M-403, M-404, M-408, M-450, M-305, M-309, M-310, M-313, M-315, M-320, M-325, M-326, M-327, M-350, M-360, M-208, M-210, M-215, M-220, M-225, M-233, M-240, M-245, M-260, M-270, M-1100, M-1200, M-1210, M-1310, M-1600, M-221, M-203, TO-924, TO-1270, TO-1231, TO-595, TO-756, TO-1343, TO-1382, TO-902, TO-904, TO-905, TO-1330 (Toagosei Co., Ltd.), Kayarad D-310, D-330, DPHA, DPCA-20, DPCA-30, DPCA-60, DPCA-120, DN-0075, DN-2475, SR-295, SR-355, SR-399E, SR-494, SR-9041, SR-368, R-415, SR-444, SR-454, SR-492, SR-499, SR-502, SR-9020, SR-9035, SR-111, SR-212, SR-213, SR-230, SR-259, SR-268, SR-272, SR-344, SR-349, SR-368, SR-601, SR-602, SR-610, SR-9003, PET-30, T-1420, GPO-303, TC-120S, HDDA, NPGDA, TPGDA, PEG400DA, MANDA, HX-220, HX-620, R-551, R-712, R-167, R-526, R-551, R-712, R-604, R-684, TMPTA, THE-330, TPA-320, TPA-330, KS-HDDA, KS-TPGDA, KS-TMPTA (Nippon Kayaku Co., Ltd.), Light Acrylate PE-4A, DPE-6A, DTMP-4A (Kyoeisha Chemical Co., Ltd.) and a combination thereof.

In one embodiment of the present invention, the photosensitive resin composition includes 1 to 10 wt %, preferably 5 to 9 wt %, and more preferably 5 to 8 wt % of the photopolymerizable compound.

The photoinitiator in the photosensitive resin composition is not specifically limited, but may initiate a free radical polymerization reaction upon absorption of light energy.

The photoinitiator may be, but not limited to, benzoin and its alkyl ether such as benzoin, benzoin methyl ether, benzoin ethyl ether, benzoin isopropyl ether, benzoin phenyl ether, benzoin acetate; acetophenones such as acetophenone, 2,2-dimethoxy-2-phenylacetophenone, 2,2-diethoxy-2-phenylacetophenone, 1,1-dichloroacetophenone; aminoacetophenones such as 2-methyl-1-[4-(methylthio)phenyl]-2-morpholinylpropan-1-one, 2-phenylmethyl-2-dimethylamino-1-(4-morpholinylphenyl)-butan-1-one; anthraquinones such as 2-methylanthraquinone, 2-ethylanthraquinone, 2-tertbutylanthraquinone, 1-chloroanthraquinone, 2-amylanthraquinone; thioxanthones and xanthones such as 2,4-dimethylthioxanthone, 2,4-diethylthioxanthone, 2-chlorothioxanthone, 2,4-diisopropylthioxanthone; ketals such as acetophenonedimethylketal, dimethylbenzophenone; benzophenones such as 4,4′-bis(N,N′-dimethyl-amino)benzophenone, 4,4′-bis(N, N′-diethyl-amino)benzophenone; acridine derivatives; phenazine derivatives; quinoxaline derivatives; triphenylphosphines; phosphine oxides such as (2,6-dimethoxybenzoyl)-2,4,4-pentyl phosphine oxide, bis(2,4,6-trimethylbenzoyl)-phenyl phosphine oxide, 2,4,6-trimethylbenzoyl-diphenyl phosphine oxide, ethyl-2,4,6-trimethylbenzoyl-phenyl phosphinate; 1-phenyl-1,2-propanedione 2-O-benzoyl oxime; 4-(2-hydroxyethoxy)Phenyl-(2-propyl)ketone; 1-aminophenyl ketones and 1-hydroxy phenyl ketones such as 1-hydroxycyclohexyl phenyl ketone, 2-hydroxyisopropyl phenyl ketone, phenyl 1-hydroxyisopropyl ketone, 4-isopropylphenyl 1-hydroxyisopropyl ketone; peroxides; and a combination thereof.

In one embodiment, the photosensitive resin composition includes 1 to 10 wt %, preferably 3 to 8 wt %, and more preferably 3 to 7 wt %, of the photoinitiator based on the total weight of the photosensitive resin composition.

The thermal curing agent preferably has a structure of formula (II):

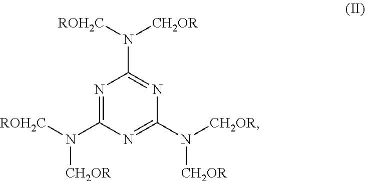

wherein R is H or CH₃.

In one embodiment, the thermal curing agent has a structure of formula (III):

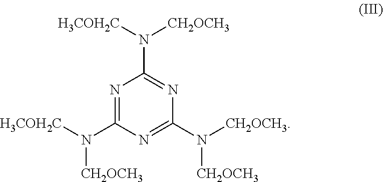

In one embodiment, the photosensitive resin composition includes 1 to 10 wt %, preferably 2 to 8 wt %, and more preferably 3 to 5 wt %, of the thermal curing agent based on the total weight of the photosensitive resin composition.

In one embodiment, the photosensitive resin composition may optionally include a solvent. The solvent is not specifically limited, but is used for dispersing or dissolving components of the photosensitive resin composition without interacting with the components. The solvent has proper volatility and dry rate, and provides smooth film. The solvent may be the common solvent in the art.

The solvent may be, but not limited to, cyclohexanone, ethyl lactate, 2-methoxyethanol, 2-methoxyacetate, propylene glycol monomethyl ether and 2-ethoxyethyl acrylate. One or more solvents may be used. When two or more solvents are mixed and used, the ratio of the mixture is not specifically limited.

In one embodiment, the photosensitive resin composition includes 30 to 80 wt %, preferably 40 to 70 wt %, and more preferably 60 to 70 wt %, of the solvent based on the total weight of the photosensitive resin composition.

In one embodiment, the photosensitive resin composition may optionally include an additive. The additive may be, but not limited to, a modifier, a toughener, a stabilizer, an antifoaming agent, a dispersant, a leveling agent, a thickening agent, a reinforcing agent, a coupling agent, a flexibility-imparting agent, a plasticizer, a sensitizer, water, a flame retardant, an antioxidant, a pigment, a dye, a filler, an anti-sediment agent, and etc.

In one embodiment, the photosensitive resin composition includes no more than 3 wt % of the additive based on the total weight of the photosensitive resin composition.

In one embodiment, the photosensitive resin composition may be used for preparing a photoresist agent, and particularly a negative photoresist agent. In such embodiment, the photosensitive resin composition is applied on a substrate, dried, exposed and developed to form a pattern. In such embodiment, after forming a pattern, the substrate is etched or plated.

In one embodiment, the photosensitive resin composition may be used for forming a protection layer or an insulation layer in an electronic component.

The photosensitive resin composition provides proper surface hardness, high transmittance, high corrosion resistance, high adhesion capability, high resolution, high reliability and high yield.

The present invention is illustrated, but not limited to, the following embodiments. In the following embodiments, the amount of a component presented as “%” and “part” is based on weight.

### EMBODIMENTS

### Preparation of Resin

### Preparation 1: Preparation of Resin 1

4 parts of a thermal free radical initiator 2,2′-azobisisbutyronitrile (AIBN), 282 parts of methyl ethyl diglycol (MEDG), 46 parts of tricyclodecanyl methacrylate (TCDMA), 21 parts of methyl acrylic acid (MAA), 3 parts of styrene, 4 parts of cyclomer M-100 (methacrylic acid, 7-oxabicyclo[4.1.0]hept-3-ylmethyl ester; Daicel Chemical Industries, Ltd.) and 12 parts of tetrahydrofurfuryl methacrylate (THFMA) were added in a flask with a condenser and a stirring device, the gas was replaced with nitrogen, and then the mixture was stirred rapidly. The temperature was kept under 65° C. for 3.5 hours, and then the temperature was raised to 75° C. for 2.5 hours. The resin 1 was then obtained.

### Preparation 2: Preparation of Resin 2

4 parts of a thermal free radical initiator 2,2′-azobisisbutyronitrile (AIBN), 282 parts of methyl ethyl diglycol (MEDG), 33 parts of tricyclodecanyl methacrylate (TCDMA), 21 parts of methyl acrylic acid (MAA), 3 parts of styrene and 45.5 parts of glycidyl methacrylate (GMA) were added in a flask with a condenser and a stirring device, the gas was replaced with nitrogen, and then the mixture was stirred rapidly. The temperature was kept under 65° C. for 3.5 hours, and then the temperature was raised to 75° C. for 2.5 hours. The resin 2 was then obtained.

### Preparation 3: Preparation of Resin 3

4 parts of a thermal free radical initiator 2,2′-azobisisbutyronitrile (AIBN), 282 parts of methyl ethyl diglycol (MEDG), 11 parts of tricyclodecanyl methacrylate (TCDMA), 20 parts of methyl acrylic acid (MAA), 3 parts of styrene and 98 parts of cyclomer M-100 (methacrylic acid, 7-oxabicyclo[4.1.0]hept-3-ylmethyl ester were added in a flask with a condenser and a stirring device, the gas was replaced with nitrogen, and then the mixture was stirred rapidly. The temperature was kept under 65° C. for 3.5 hours, and then the temperature was raised to 75° C. for 2.5 hours. The resin 3 was then obtained.

### Preparation 4: Preparation of Resin 4

4 parts of a thermal free radical initiator 2,2′-azobisisbutyronitrile (AIBN), 282 parts of methyl ethyl diglycol (MEDG), 42 parts of tricyclodecanyl methacrylate (TCDMA), 14 parts of methyl acrylic acid (MAA) and 90 parts of cyclomer M-100 (methacrylic acid, 7-oxabicyclo[4.1.0]hept-3-ylmethyl ester) were added in a flask with a condenser and a stirring device, the gas was replaced with nitrogen, and then the mixture was stirred rapidly. The temperature was kept under 65° C. for 3.5 hours, and then the temperature was raised to 75° C. for 2.5 hours. The resin 4 was then obtained.

### Preparation 5: Preparation of Resin 5

4 parts of a thermal free radical initiator 2,2′-azobisisbutyronitrile (AIBN), 282 parts of methyl ethyl diglycol (MEDG), 94 parts of tricyclodecanyl methacrylate (TCDMA), 11 parts of methyl acrylic acid (MAA) and 40 parts of cyclomer M-100 (methacrylic acid, 7-oxabicyclo[4.1.0]hept-3-ylmethyl ester) were added in a flask with a condenser and a stirring device, the gas was replaced with nitrogen, and then the mixture was stirred rapidly. The temperature was kept under 65° C. for 3.5 hours, and then the temperature was raised to 75° C. for 2.5 hours. The resin 5 was then obtained.

### Preparation of a Photosensitive Resin Composition

### Embodiment 1

47.47 parts of the resin 1 solution prepared from Preparation 1, 3.08 parts of a photoinitiator IRGACURE®907 (Ciba Inc.), 7.02 parts of the monomer with multiple groups “Aronix M 400” (Toagosei Co., Ltd.), 2 parts of a thermal curing agent “CYMEL 303” (Cytec Industries Inc.) and 40.43 parts of a solvent “propylene glycol monomethyl ether acetate” (PGMEA) were mixed and filtered with a 10 μm filter.

### Embodiment 2

The steps of Embodiment 1 were repeated to form a photosensitive resin composition except that the resin 1 was replaced with the resin 2 prepared from Preparation 2.

### Embodiment 3

The steps of Embodiment 1 were repeated to form a photosensitive resin composition except that the resin 1 was replaced with the resin 3 prepared from Preparation 3.

### Embodiment 4

The steps of Embodiment 1 were repeated to form a photosensitive resin composition except that the resin 1 was replaced with the resin 4 prepared from Preparation 4.

### Embodiment 5

The steps of Embodiment 1 were repeated to form a photosensitive resin composition except that the resin 1 was replaced with the resin 5 prepared from Preparation 5.

### Comparative Example 1

The steps of Embodiment 1 were repeated to form a photosensitive resin composition except that the resin 1 was replaced with the commercial resin BL-100 (LIDYE CHEMICAL CO., LTD.)

### Comparative Example 2

The steps of Embodiment 1 were repeated to form a photosensitive resin composition except that the resin 1 was replaced with the commercial resin 295 (DIC Corporation).

### Comparative Example 3

The steps of Embodiment 1 were repeated to form a photosensitive resin composition except that the thermal curing agent CYMEL 303 was not added in Comparative Example 3.

### Comparative Example 4

The steps of Embodiment 3 were repeated to form a photosensitive resin composition except that the thermal curing agent CYMEL 303 was not added in Comparative Example 4.

### Comparative Example 5

The steps of Comparative Example 1 were repeated to form a photosensitive resin composition except that the thermal curing agent CYMEL 303 was not added in Comparative Example 5.

### Comparative Example 6

The steps of Comparative Example 2 were repeated to form a photosensitive resin composition except that the thermal curing agent CYMEL 303 was not added in Comparative Example 6.

The components of the resin compositions in Embodiments 1-5 and Comparative Examples 1-6 are listed in Table 1.

TABLE 1

| | Resin | | M400 | IRGACURE ® 907 | CYMEL 303 | PGMEA |
|---|---|---|---|---|---|---|
| | (amount (parts)) | | (parts) | (parts) | (parts) | (parts) |
| Embodiment 1 | Resin 1 | 47.47 | 7.02 | 3.08 | 2.0 | 40.43 |
| Embodiment 2 | Resin 2 | 47.47 | 7.02 | 3.08 | 2.0 | 40.43 |
| Embodiment 3 | Resin 3 | 47.47 | 7.02 | 3.08 | 2.0 | 40.43 |
| Embodiment 4 | Resin 4 | 47.47 | 7.02 | 3.08 | 2.0 | 40.43 |
| Embodiment 5 | Resin 5 | 47.47 | 7.02 | 3.08 | 2.0 | 40.43 |
| Comparative | Resin 6 | 47.47 | 7.02 | 3.08 | 2.0 | 40.43 |
| Example 1 | | | | | | |
| Comparative | Resin 7 | 47.47 | 7.02 | 3.08 | 2.0 | 40.43 |
| Example 2 | | | | | | |
| Comparative | Resin 1 | 47.47 | 7.02 | 3.08 | — | 42.43 |
| Example 3 | | | | | | |
| Comparative | Resin 3 | 47.47 | 7.02 | 3.08 | — | 42.43 |
| Example 4 | | | | | | |
| Comparative | Resin 6 | 47.47 | 7.02 | 3.08 | — | 42.43 |
| Example 5 | | | | | | |
| Comparative | Resin 7 | 47.47 | 7.02 | 3.08 | — | 42.43 |
| Example 6 | | | | | | |

### Test

The adhesion, surface hardness and transmittance of the resin compositions in the above Embodiments and Comparative Examples were tested.

The resin compositions of the above Embodiments and Comparative Examples were respectively coated on a conductive glass substrate with ITO by spinning coating (1000 rpm, 7 seconds). Each substrate was soft baked in an oven at 100° C. for 10 minutes. The resin composition was exposed via a mask under the exposure energy 150 mJ/cm². After rinse with deionized water for 30 seconds, a post-bake was performed at 230° C. for 30 minutes. The thin film formed by the resin composition on the substrate was tested according the following methods in order to evaluate characteristics of the resin composition.

### (1) Adhesion Upon Etching

The substrate formed with a thin film of a resin composition was immersed in an acidic etching solution (HCl: 215 ml, 37 wt %; H₂O: 69.2 ml; FeCl₃: 16.8 ml, 15 wt %) at 40° C. for 3 minutes. Then, the adhesion of the thin film to the substrate upon etching was tested according to JIS K-5400-1990 8.5.3. In this evaluation, the best adhesion was indicated as 5B, and the worst adhesion was indicated as 0B.

As shown in Table 2, the photosensitive resin composition of the present invention had great resistance to the etching solution upon exposure, and had great adhesion to the substrate upon etching.

### (2) Surface Hardness

The surface hardness of the thin film formed by the resin composition was tested by the pencil scratch hardness test. The result was shown in Table 2, wherein the best hardness was indicated as 6H, and the worst hardness was indicated as 6B. For example, if the H pencil and the 2H pencil made no scratch on the surface but the 3H made a scratch on the surface, the hardness of the sample was indicated as 2H.

As shown in Table 2, the photosensitive resin composition provided great surface hardness.

### (3) Transmittance at 230° C.

The light transmittance of the thin film formed by the resin composition was determined at wavelengths of 390 nm, 400 nm and 450 nm by a microspectrophotometer (MX-50; Olympus). The result was shown in Table 2. As shown in Table 2, the photosensitive resin composition of the present invention provided great adhesion, great surface hardness and high transmittance.

TABLE 2

| | | Surface | | | |
|---|---|---|---|---|---|
| | Adhesion | hardness | Transmittance at 230° C. | | |
| | upon etching | of thin film | 390 nm | 400 nm | 450 nm |
| Embodiment 1 | 5B | 3H | 94.56 | 96.05 | 96.67 |
| Embodiment 2 | 3B | 4H | 95.77 | 94.5 | 97.49 |
| Embodiment 3 | 5B | 3H | 96.98 | 96.17 | 96.77 |
| Embodiment 4 | 5B | 3H | 92.81 | 95.9 | 99.07 |
| Embodiment 5 | 5B | H | 92.4 | 96.41 | 97.28 |
| Comparative | 4B | 6B | 92.43 | 93.73 | 97.12 |
| Example 1 | | | | | |
| Comparative | 4B | <6B | 94.12 | 93.26 | 95.88 |
| Example 2 | | | | | |
| Comparative | 2B | 3H | 95.24 | 95.5 | 97.95 |
| Example 3 | | | | | |
| Comparative | 2B | 3H | 97.19 | 97.85 | 97.27 |
| Example 4 | | | | | |
| Comparative | 2B | 6B | 92.33 | 93.58 | 97.32 |
| Example 5 | | | | | |
| Comparative | Opaque* | opaque | opaque | opaque | opaque |
| Example 6 | | | | | |

Opaque indicates that the surface of the thin film is not transparent after the post-bake.

The photosensitive resin composition of the present invention provides great adhesion, surface hardness and transmittance to meet industrial requirements.

The invention has been described using exemplary preferred embodiments. However, it is to be understood that the scope of the invention is not limited to the disclosed arrangements. The scope of the claims, therefore, should be accorded the broadest interpretation, so as to encompass all such modifications and similar arrangements.

What is claimed is:

1. A photosensitive resin composition, comprising:
10 to 50 wt % of an alkali soluble resin based on a total weight of the photosensitive resin composition, wherein the alkali soluble resin comprises a monomer selected from the group consisting of an acrylic monomer, an acrylic anhydride and a mixture thereof, and an acrylic monomer with an epoxy structure;
1 to 10 wt % of a photopolymerizable compound having an ethylenically unsaturated bond based on the total weight of the photosensitive resin composition;
1 to 10 wt % of a photoinitiator based on the total weight of the photosensitive resin composition; and
1 to 10 wt % of a thermal curing agent based on the total weight of the photosensitive resin composition.

2. The photosensitive resin composition of claim 1, wherein the acrylic monomer is acrylic acid or methyl acrylic acid.

3. The photosensitive resin composition of claim 1, wherein the acrylic monomer with the epoxy structure has a structure of formula (I):

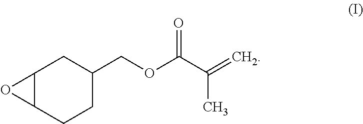

4. The photosensitive resin composition of claim 1, wherein the alkali soluble resin has an average molecular weight in a range of from 5000 to 15000.

5. The photosensitive resin composition of claim 1, wherein a weight ratio of the monomer selected from the group consisting of the acrylic monomer, the acrylic anhydride and the mixture thereof to the acrylic monomer with the epoxy structure is in a range of from 1:0.8 to 1:3.

6. The photosensitive resin composition of claim 1, wherein the thermal curing agent has a structure of formula (II): 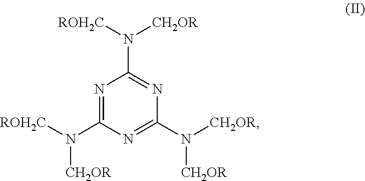
wherein R is H or CH₃.

7. The photosensitive resin composition of claim 6, wherein the thermal curing agent is based on the total weight of the photosensitive resin composition.

8. The photosensitive resin composition of claim 1, further comprising a solvent.

9. The photosensitive resin composition of claim 8, comprising 60 to 70 wt % of the solvent based on the total weight of the photosensitive resin composition.

10. The photosensitive resin composition of claim 1, further comprising an additive.
